(19) United States
(12) Patent Application Publication
(10) Pub. No.: US 2002/0106905 A1
(43) Pub. Date: Aug. 8, 2002

(54) Method for removing copper from a wafer edge

(75) Inventors: Minh Q. Tran, Milpitas, CA (US); Richard J. Huang, Cupertino, CA (US)

Correspondence Address: McDERMOTT, WILL & EMERY, 600 13th Street, N.W., Washington, DC, 20005-3096, US

(73) Assignee: Advanced Micro Devices, Inc.

(21) Appl. No.: 09/778,065

(22) Filed: Feb. 7, 2001

(51) Int. Cl. H01L 21/302; H01L 21/461

(52) U.S. Cl. 438/754

(57) ABSTRACT

A method for removing copper from the edge of a semiconductor wafer to prevent particle and copper contamination provides a photoresist or other protective layer on top of the copper. An edge bead removal process is performed on the photoresist to expose the edge of the copper on the semiconductor wafer. An etchant that is selective to the copper and does not attack photoresist material is applied to the semiconductor wafer. The edge of the copper, which forms the potential source of particle or copper contamination, is thereby etched. The remaining copper, protected by the photoresist layer, remains unexposed to the etchant. After the copper edge has been removed, the photoresist material is also removed to expose the protected underlying copper for further processing.

### FIELD OF THE INVENTION

The present invention relates to the field of semiconductor processing, and more particularly, to the removal of copper from the edge of a semiconductor wafer.

### BACKGROUND OF THE INVENTION

In semiconductor processing, copper has been increasingly chosen as the material to replace aluminum in an effort to reduce the size of lines and vias in electrical circuit. This is because the conductivity of copper is twice that of aluminum and over three times that of tungsten. As a result, the same current can be carried through a copper line having half the width of an aluminum line. Also, the electromigration characteristics of copper are superior to those of aluminum. Some problems with the use of copper in semiconductor processing includes the potential contamination by copper of many of the materials used in semiconductor processing. Therefore, care must be taken to prevent copper from migrating. Barrier metals are often employed to act as a diffusion barrier to the copper.

Connections between metal levels, which are separated by dielectric inter-levels, are typically formed with a damascene method of via formation between metal levels. The underlying copper film is first completely covered with the dielectric. A typical dielectric is silicon dioxide. A patterned photoresist profile is then formed over the dielectric. The resist profile has an opening, or hole, in the photoresist corresponding to the area in the dielectric in which the via is to be formed. Other areas of the dielectric to be left in place are covered with photoresist. The dielectric not covered with photoresist is then etched to remove oxide underlying the hole in the photoresist. The photoresist is then stripped away. A thin film of copper, or some other metallic material, is then deposited to fill the via. This deposition also leaves excess copper on areas above the vias. The excess copper remaining is removed with a chemical mechanical polish (CMP) process, as is well known in the art. The result is an inlaid or damascene structure.

Even though circuit structures are masked to prevent copper deposition, and undesired copper is removed in the CMP process, copper may still remain on the edges and sides of the wafer where no integrated circuits are located, as a result of the deposition and polishing processes. On these edges, copper may migrate to neighboring active regions on the sides and edges of the wafer. Furthermore, copper from a wafer edge may contaminate the wafer transport system, and be passed on to contaminate other wafers. Also, when the copper film has been electroplated, the subsequent copper polishing of the copper film will delaminate a poorly adhered electroplated copper film.

Conventional methods of removing copper from the wafer edge includes direct etching with an edge-spray tool or backside cleaning tool with etching which wraps around the front side. The wafer is then spun and nitric acid is applied at the edge of the wafer to etch the copper. Following the etching of the copper with nitric acid, the photoresist material is removed. One concern with this approach is the use of nitric acid to etch the copper. Nitric acid may also etch the photoresist material that is supposed to protect the copper layer from damage. This unintentional etching of the photoresist material can improperly expose the underlying copper layer portion that is supposed to be protected. Hence, the use of nitric acid requires the spinning (i.e. rotation) of the wafer and application of the nitric acid at an edge of the wafer during the spinning so that the nitric acid will not attack the photoresist covering the protected area of the layer of copper.

### SUMMARY OF THE INVENTION

There is a need for a method of removing the copper from an edge of a semiconductor wafer in a manner that allows the wafer to remain rotationally stationary, and further with minimizing risk of damage to the layer of copper that is not supposed to be removed.

These and other needs are met by embodiments of the present invention which provide a method of removing conductive material at a wafer edge. The method comprises the steps of forming a protective layer on a conductive metal layer of a wafer such that only the edge of the conductive metal layer is exposed. The exposed conductive metal layer edge is etched with an etchant that is selective for the conductive metal layer and does not substantially etch the protective layer. In certain preferred embodiments, the protective layer is a photoresist and the conductive metal layer is copper or copper alloyed.

By providing an etchant that is selective for the conductive metal layer and does not substantially etch the protective layer, the invention assures that the protective layer is not unintentionally etched during the removal of the conductive metal layer edge. This also has the advantage of allowing the wafer to remain rotationally stationary, as there is no risk that the etchant will etch through the protective layer and damage the conductive metal layer. An edge-spray tool or an immersion bath may be employed to provide etchant on both the protective layer and the exposed conductive metal layer edge. At the same time, a conductive metal layer (e.g., copper) at the wafer edge may be readily removed to prevent subsequent contamination by the conductive metal.

The earlier stated needs are also met by other aspects of the present invention which provide a method of removing copper from a wafer edge, comprising the steps of masking with a protective layer a top surface of a wafer to cover a portion of the top surface and expose a wafer edge at which copper is present. The wafer is exposed to an etchant that is selective for copper to remove the copper at the wafer edge without substantially etching the protective layer.

The foregoing and other features, aspects, and advantages of the present invention will become more apparent from the following detailed description of the present invention when taken in conjunction with the accompanying drawings.

### BRIEF DESCRIPTION OF THE DRAWINGS

FIG. 1A depicts a top view of a semiconductor wafer following the formation of a copper layer over the top surface of the semiconductor wafer.

FIG. 1B depicts a schematic depiction of a cross-section of an edge portion of the semiconductor wafer of FIG. 1A, taken along lines IB-IB.

FIG. 2A depicts the top view of the semiconductor wafer of FIG. 1A, following the deposition of a protective layer over the top surface of the semiconductor wafer.

FIG. 2B depicts a schematic cross-section of the edge of the semiconductor wafer of FIG. 2A, taken along lines IIB-IIB.

FIG. 3A depicts a top view of the semiconductor wafer of FIG. 2A, following the removal of a portion of the protective layer to expose the edge of a conductive material, in accordance with embodiments of the present invention.

FIG. 3B depicts a schematic cross-section of the semiconductor wafer of FIG. 3A taken along the line IIIB-IIIB.

FIG. 4A is a top view of the semiconductor wafer FIG. 3A after the conductive metal layer have been etched from the edge of the semiconductor wafer in accordance with embodiments of the present invention.

FIG. 4B is a cross-section of the schematic depiction of the edge portion of the semiconductor wafer of FIG. 4A, taken along line IVB-IVB.

FIG. 5A is a top view of the semiconductor wafer of FIG. 4A, after the protective layer has been removed in accordance with the embodiments of the present invention.

FIG. 5B is a schematic depiction of the cross-section of an edge portion of the semiconductor wafer 5A, taken along line VB-VB.

FIG. 6 is a schematic depiction of a side view of an arrangement for etching the wafer edge to remove conductive metal from the edge of the wafer in accordance with embodiments of the present invention.

FIG. 7 is a view of an alternative arrangement for removing the conductive metal from the edge of a wafer in accordance with embodiments of the present invention.

### DETAILED DESCRIPTION OF THE INVENTION

The present invention addresses problems related to the contamination of wafer transport systems and semiconductor wafers created by copper present at the edges of a semiconductor wafer, and more particularly, the problems in removing the copper at the wafer edge by conventional techniques. These problems are solved, in part, by the present invention which provides a protective layer, such as photoresist, over the top surface of a conductive metal layer, such as copper, on a semiconductor wafer. The semiconductor wafer is then exposed to an etchant that is selective to etch the exposed copper at the edge of the wafer, with the protective layer serving to protect the copper that is underneath it. The etchant is selective so that it does not attack the photoresist material. This permits a rotationally stationary apparatus to be employed to etch the ends of the wafer to remove the copper and thereby prevent copper contamination.

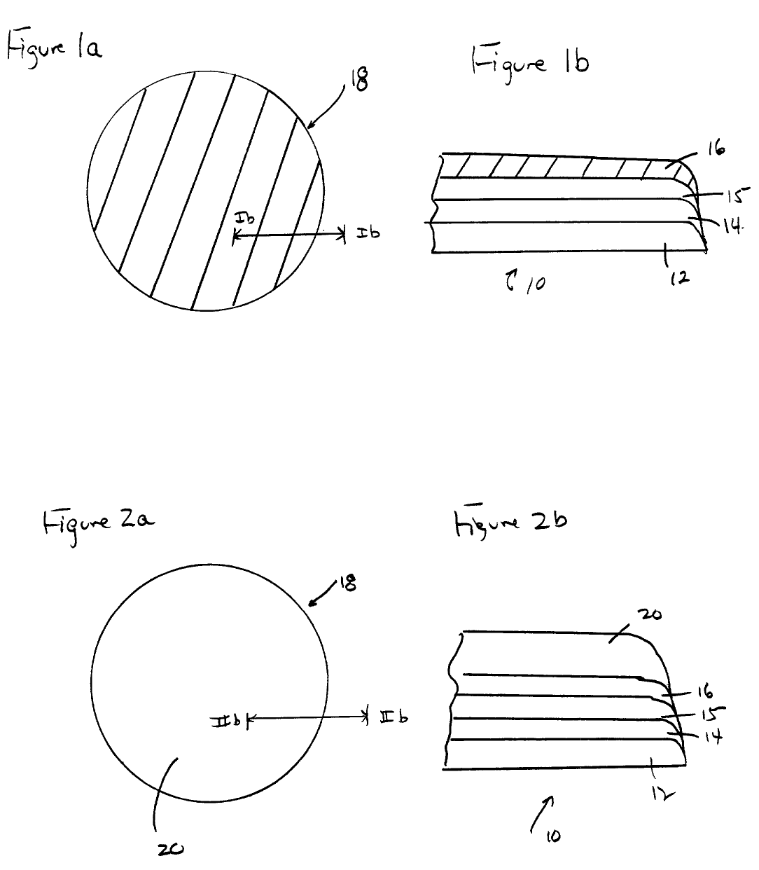

FIG. 1A depicts a top surface of a semiconductor wafer that has been provided with a copper layer 16 on its upper surface. The cross-section of an edge portion, taken along line IB-IB, shows the semiconductor wafer 10 as a substrate 12 on which a barrier metal 14 has been deposited, such as titanium nitride, tungsten, molybdenum, etc. Such barrier metals prevent the diffusion of copper into the substrate 12.

The semiconductor wafer 10 has a copper seed layer 15 provided on the barrier metal 14. A conductive metal layer, such as copper, is deposited as layer 16 on the top of the semiconductor wafer. The copper layer 16 may be formed by electroplating, as is well known to those of ordinary skill in the art.

As depicted in FIG. 1B, the edge of the semiconductor wafer 18 has a bevel which is precluded from being removed by copper polishing, by CMP, for example. Hence, the remaining copper is a potential source of particle and copper contamination due to mechanical impact of this soft material with a wafer cassette. The present invention provides a method for removing edge copper that is a potential source of particle or copper contamination in an efficient and cost-effective manner.

FIG. 2A depicts the top surface of the semiconductor wafer after a protective layer 20 has been deposited over the copper layer 16. The protective layer 20 may be made of photoresist, for example, although other types of protective layers may be employed. Another example of a protective layer may be spin-on glass. Photoresist is an especially advantageous material to use as the protective layer since it is readily deposited and patterned. As seen in FIG. 2B, the photoresist in protective layer 20 extends out to the edge of the semiconductor wafer 10 so as to completely cover the top of the copper layer 16. However, the edge of the copper needs to be removed, so that the photoresist in the protective layer 20 must be patterned to expose the edge of the copper.

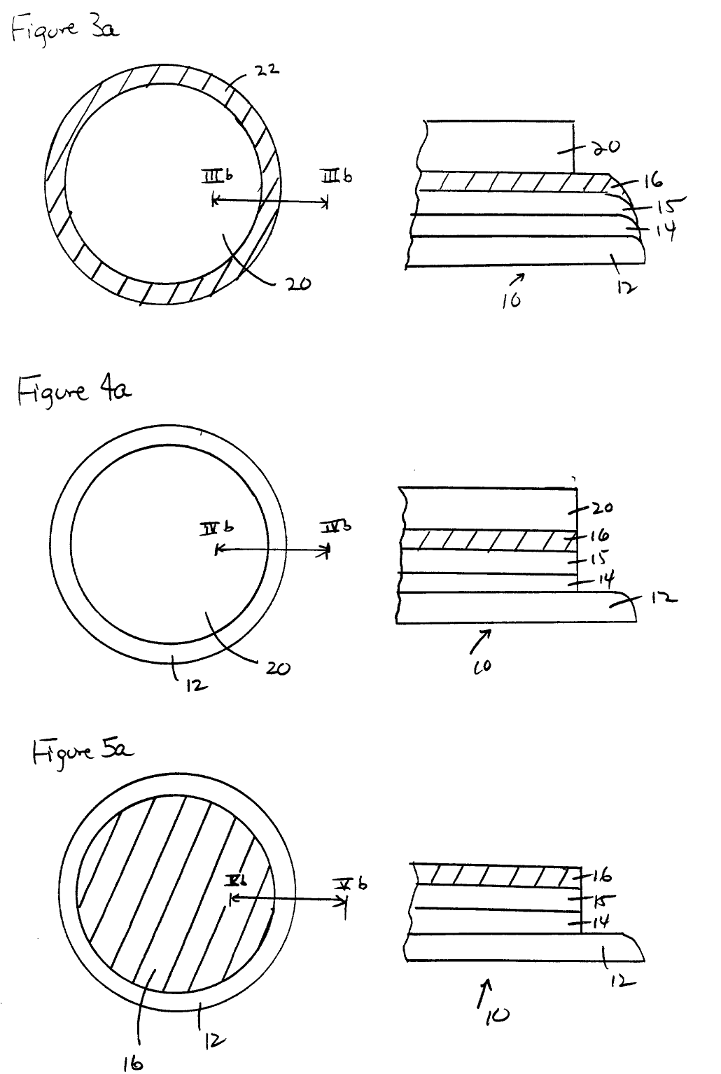

In FIG. 3A, a conventional edge-bead removal process is performed to create a ring 22 (as seen in the top view of FIG. 3A of exposed conductive material (e.g., copper). The photoresist may be removed in the edge bead removal process by a photoresist removal solvent.

With the edge 18 of the copper now exposed following the edge bead removal process to pattern the protective layer 20, the copper is now etched at the edge 18 of the semiconductor wafer 10. The present invention employs an etchant that is selective to the copper 16 and does not significantly attack or etch the protective layer 20. An exemplary etchant that may be used when the conductive material is copper and the protective layer is photoresist is ammonium persulfate. The ammonium persulfate, when applied over the wafer 10, may come in contact with the photoresist in the protective layer 20 without concern that the photoresist 20 will be removed and the underlying copper 16 being damaged unintentionally. Instead, only the edge 18 of the copper 16 is etched. The result of the etching is depicted in FIGS. 4A and 4B.

In FIGS. 5A and 5B, the photoresist in protective layer 20 has been removed by conventional removal techniques. This exposes the copper in the conductive metal layer 16 that was previously protected by the photoresist in the protective layer 20. As can be appreciated by FIG. 5B, the copper edge has been removed, while the copper 16 in the center of the semiconductor wafer 10 has been protected. This has been accomplished in a rotationally stationary manner, in accordance with the embodiments of the present invention. This avoids the need for an expensive rotational tool dedicated to removing the copper edge, as required in some prior art methodologies.

FIG. 6 depicts a schematic view of a spray tool 30 that sprays the etchant 32 (e.g., ammonium persulfate solution) over the entire wafer top surface. Since the entire wafer top surface may be sprayed with the etchant, rather than just the edge of the wafer, a rotational motion of the wafer is not necessary in order to exclude the etchant from contacting the photoresist material.

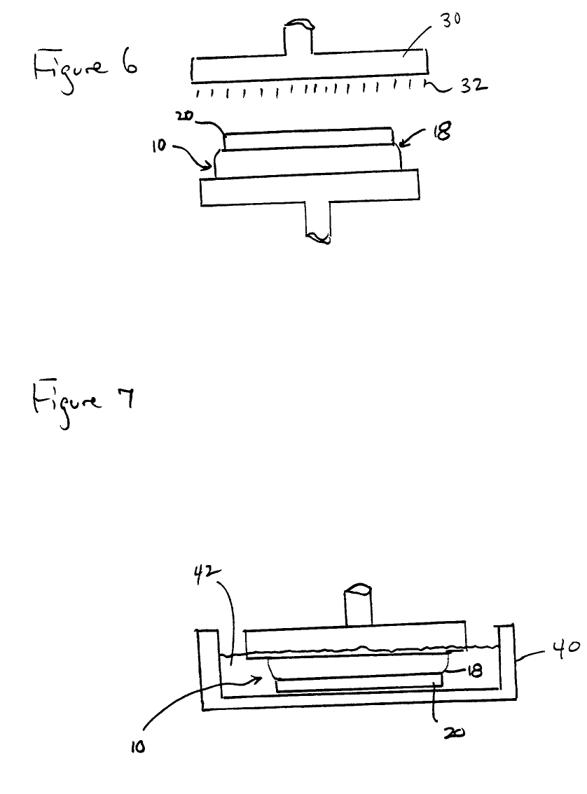

In another embodiment, depicted in FIG. 7, the semiconductor wafer 10 is immersed in a bath 40 of etchant 42 so that the protective layer 20 and the edge 18 of the copper layer 16 are immersed in etchant. However, despite this immersion, only the copper at the edge 18 is substantially etched due to the use of a selective etchant, such as ammonium persulfate solution.

In both FIGS. 6 and 7, the wafer 10 does not need to be rotated. The wafer may thus remain rotationally stationary throughout the etching of the copper 16 from the edge 18 of the wafer 10.

Although the present invention has been described and illustrated in detail, it is to be clearly understood that the same is by way of illustration and example only and is not to be taken by way of limitation, the scope of the present invention being limited only by the terms of the appended claims.

What is claimed is:

1. A method of removing a conductive metal at a wafer edge, comprising the steps of:
forming a protective layer on a conductive metal layer of a wafer such that an edge of the conductive metal layer is exposed; and
etching the exposed conductive metal layer edge with an etchant that is selective for the conductive metal layer and does not substantially etch the protective layer.

2. The method of claim 1, wherein the protective layer is a photoresist.

3. The method of claim 2, wherein the etchant is ammonium persulfate solution.

4. The method of claim 3, further comprising removing the photoresist of the protective layer after the exposed conductive metal layer edge is etched to thereby expose a non-etched region of the conductive metal layer.

5. The method of claim 4, wherein the conductive metal layer is copper or a copper alloy.

6. The method of claim 5, wherein the step of forming a protective layer includes depositing the photoresist on the conductive metal layer and removing an edge bead of the photoresist.

7. The method of claim 6, wherein the step of etching the exposed metal conductive layer includes spraying the ammonium persulfate solution over the wafer, including the protective layer and the exposed conductive metal layer edge.

8. The method of claim 6, wherein the step of etching the exposed metal conductive layer includes immersing the wafer in a bath of ammonium persulfate.

9. A method of removing copper from a wafer edge, comprising the steps of:
masking with a protective layer a top surface of a wafer to cover a portion of the top surface and expose a wafer edge at which copper is present; and
exposing the wafer to an etchant that is selective for copper to remove the copper at the wafer edge without substantially etching the protective layer.

10. The method of claim 9, wherein the step of masking includes forming the protective layer over a copper layer, and patterning the protective layer to expose the copper at the wafer edge.

11. The method of claim 10, wherein the protective layer is photoresist.

12. The method of claim 11, wherein the etchant comprises ammonium persulfate solution.

13. The method of claim 12, wherein the etchant is sprayed on the photoresist and the exposed copper.

14. The method of claim, wherein the wafer is immersed in a bath such that the photoresist and the exposed copper are immersed in ammonium persulfate solution.

15. The method of claim 9, wherein the etchant is sprayed over the covered portion of the top surface of the wafer and the exposed copper at the wafer edge.

16. The method of claim 15, wherein the etchant is ammonium persulfate solution.

17. The method of claim 9, wherein the wafer is immersed in a bath such that the covered portion of the top surface of the wafer and the exposed copper at the wafer edge are immersed in the etchant.

18. The method of claim 17, wherein the etchant is ammonium persulfate solution.

19. The method of claim 9, wherein the wafer is rotationally stationary during the exposing of the wafer to an etchant.

20. The method of claim 11, further comprising removing the photoresist with photoresist solvent to expose the portion of the top surface of the wafer that was masked.
